(19) United States
(12) Patent Application Publication
(10) Pub. No.: US 2011/0057643 A1
(43) Pub. Date: Mar. 10, 2011

(54) OSCILLOGRAPH AND SIGNAL INTEGRITY TEST METHOD USING THE OSCILLOGRAPH

(75) Inventors: WANG-DING SU, Tu-Cheng (TW); JUI-HSIUNG HO, Tu-Cheng (TW); YUNG-CHENG HUNG, Tu-Cheng (TW)

(73) Assignee: HON HAI PRECISION INDUSTRY CO., LTD., Tu-Cheng (TW)

(21) Appl. No.: 12/636,768

(22) Filed: Dec. 13, 2009

(30) Foreign Application Priority Data
Sep. 7, 2009 (CN) 200910306637.2

(51) Int. Cl. G01R 23/02

(52) U.S. Cl. 324/76.39

(57) ABSTRACT

A oscillograph and a signal integrity test method are provided. The oscillograph measures a serial data bus to obtain captured signals transmitted by each communication channel of the oscillograph. By identifying a time sequence for the captured signals transmitted by each communication channel, a test signal is determined. The oscillograph measures a clock frequency of the test signal, sampling a part of the test signal, and testing the part according to pre-set test items. If a predetermined number of samples of the test signal is tested, the oscillograph constitutes a completed signal integrity test of the serial data bus and a test report is generated.

### BACKGROUND

1. Technical Field

Embodiments of the present disclosure generally relate to signal test methods, and more particularly to a signal integrity test method using an oscillograph.

2. Description of Related Art

A serial data bus test is generally performed using an oscillograph. In order to accomplish the serial data bus test, the oscillograph measures signals from the serial data bus, identifies time sequence from each communication channel, and determines a sending port and a receiving port for each of the captured signals accordingly. After the serial data bus is tested, a signal integrity test of the serial data bus is performed manually. However, manual testing has many shortcomings, such as: (a) time sequence determined visually is often error prone; (b) a plurality of serial data buses cannot be tested synchronously; (c) cannot perform a bulk sampling in a short time; and (d) inconsistent results because of human operator.

What is needed, therefore, is a signal integrity test method to overcome the aforementioned problems.

### BRIEF DESCRIPTION OF THE DRAWINGS

FIG. 1 is a block diagram of one embodiment of an oscillograph.

FIG. 2 is a flowchart illustrating one embodiment of a signal integrity test method for a serial data bus by using the oscillograph of FIG. 1.

FIG. 3 is one block of FIG. 2 in detail, namely identifying a time sequence for captured signals transmitted by each communication channel of the oscillograph, to determine a test signal.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

In general, the word “module,” as used herein, refers to logic embodied in hardware or firmware, or to a collection of software instructions, written in a programming language, such as, for example, Java, C, or assembly. One or more software instructions in the modules may be embedded in firmware, such as an EPROM. It will be appreciated that modules may comprised connected logic units, such as gates and flip-flops, and may comprise programmable units, such as programmable gate arrays or processors. The modules described herein may be implemented as either software and/or hardware modules and may be stored in any type of computer-readable medium or other computer storage device.

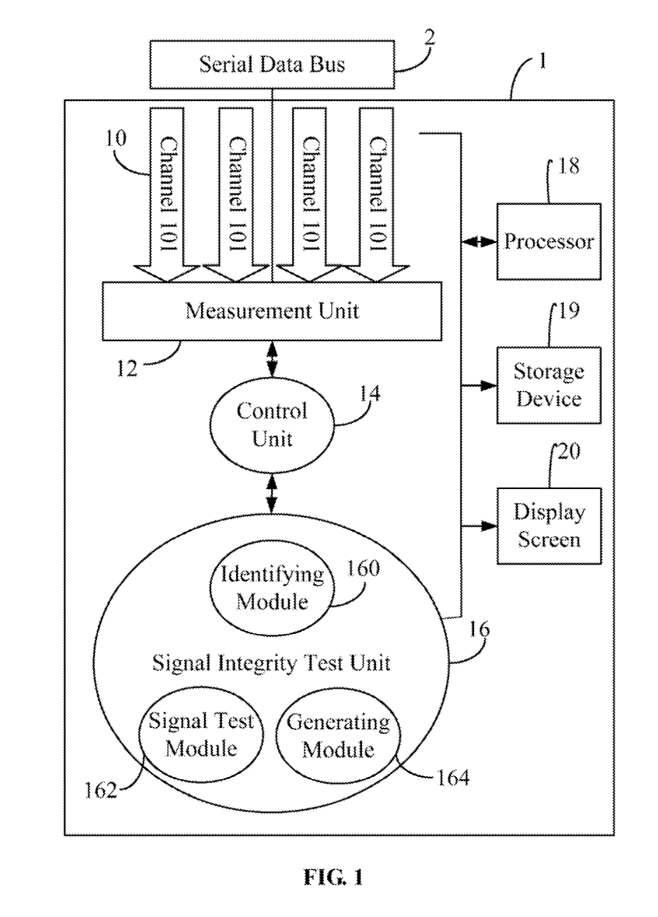

FIG. 1 is a block diagram of one embodiment of an oscillograph 1. The oscillograph 1 typically includes at least four communication channels 10 labeled channel 101, channel 102, channel 103 and channel 104, a measurement unit 12, a control unit 14, and a signal integrity test unit 16. In the embodiment, the oscillograph 1 connects to a serial data bus 2 via the at least four communication channels 10. The oscillograph 1 is operable to perform a signal integrity test on the serial data bus 2 by using the measurement unit 12, the control unit 14, and the signal integrity test unit 16. For example, the measurement unit 12 communicates with the serial data bus 2 to obtain signals. The control unit 14 controls the oscillograph 1 to capture the signals (hereinafter referred to as “captured signals”) transmitted by each of the at least four communication channels 10. The signal integrity test unit 16 determines a captured signal to be tested (hereinafter as “test signal”) from the captured signals, and performs the signal integrity test on the test signal and generates a test report. The signal integrity test method will be described in greater detail below.

The oscillograph 1 further includes at least one processor 18, a storage device 19, and a display screen 20. Each of the measurement unit 12, the control unit 14, and the signal integrity test unit 16 may include one or more computerized instructions or codes, which is stored in the storage device 19, and can be executed by the at least one processor 18. The storage device 19 may be a hard disk drive, a compact disc, a digital video disc, or a tape drive.

In the embodiment, the signal integrity test unit 16 may include an identifying module 160, a signal test module 162, and a generating module 164. One or more computerized codes of the identifying module 160, the signal test module 162, and the generating module 164 may be stored in the storage device 19, and can be executed by the at least one processor 18.

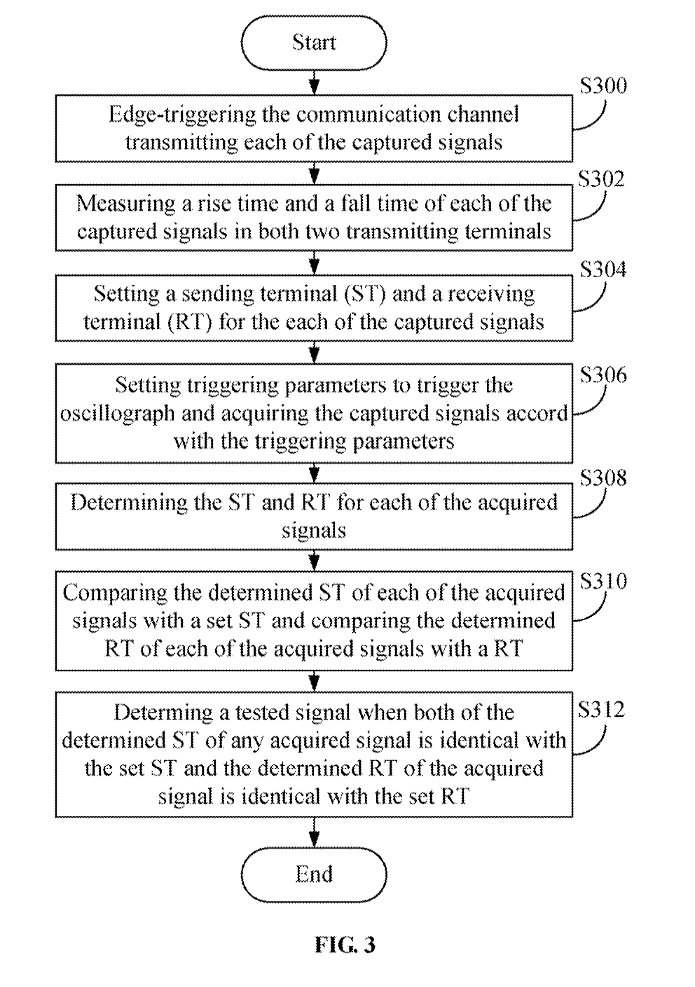

The identifying module 160 is operable to determine the test signal by identifying a time sequence for the captured signals transmitted by each of the at least four communication channels 10. The identifying method will be in greater detail in FIG. 3.

The signal test module 162 is operable to control the oscillograph 1 to measure a clock frequency of the test signal by positioning a sequential waveform of the test signal on a central of the display screen 20. The signal test module 162 is further operable to sample a part of the test signal, position the part according to the clock frequency, and test the part according to test items pre-set by a user. A predetermined number of samples of the test signal by the signal test module 162 constitute a completed signal integrity test of the serial data bus 2. In the embodiment, the test items include testing a high voltage, a low voltage, a frequency, a period, a rise time, a fall time, a setup time, and a hold time, for example.

The generating module 164 is operable to generate a test report. The test report records the high voltage, the low voltage, the frequency, the period, the rise time, the fall time, the setup time, and the hold time of the serial data bus 2, for example.

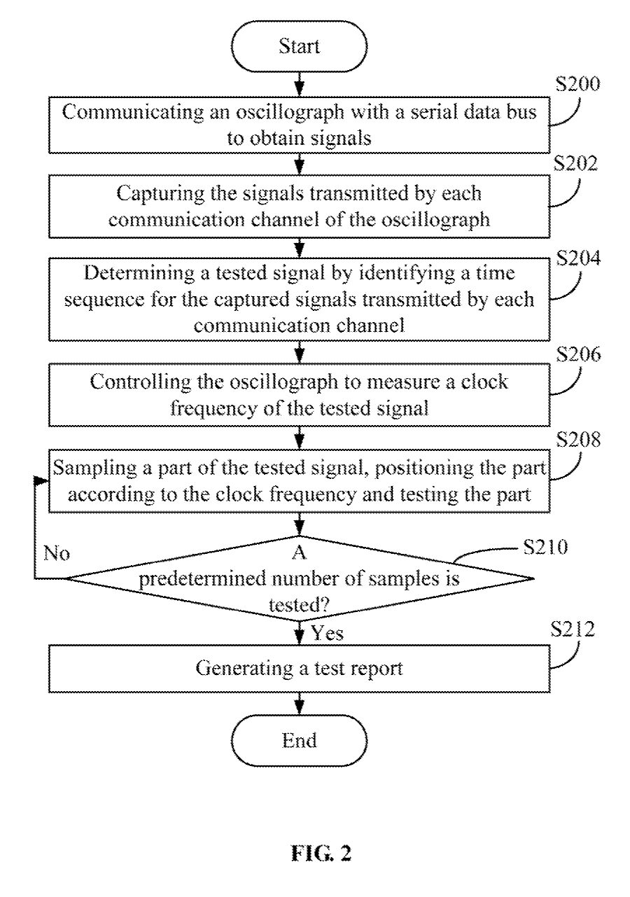

FIG. 2 is a flowchart illustrating one embodiment of a method for testing signals of the serial data bus 2 by using the oscillograph 1 of FIG. 1.

In block S200, the measurement unit 12 communicates with the serial data bus 2, to obtain signals.

In block S202, the control unit 14 controls the oscillograph 1 to capture the signals transmitted by each of the at least four communication channels 10.

In block S204, the identifying module 160 determines a test signal from the captured signals by identifying a time sequence for the captured signals transmitted by each of the at least four communication channels 10.

In block S206, the signal test module 162 controls the oscillograph 1 to measure a clock frequency of the test signal by positioning a sequential waveform of the test signal on a central of the display screen 20.

In block S208, the signal test module 162 samples a part of the test signal, positions the part on the display screen 20 according to the clock frequency, and tests the part according to test items pre-set by a user. The test items may include testing a high voltage, a low voltage, a frequency, a period, a rise time, a fall time, a setup time, and a hold time, for example.

In block S210, the signal test module 162 determines whether a predetermined number of samples of the test signal is tested. If the predetermined number of samples is tested, the signal integrity test unit 16 constitute a completed signal integrity test of the serial data bus 2, and the flow enters into block S212. If any of the predetermined number of samples is not tested, the flow returns to block S208.

In block S212, the generating module 164 generates a test report. In the embodiment, the test report records the high voltage, the low voltage, the frequency, the period, the rise time, the fall time, the setup time, and the hold time of the serial data bus 2, for example.

FIG. 3 is block S204 of FIG. 2 in detail, namely identifying a time sequence for the captured signals transmitted by each of the at least four communication channels 10, to determine the test signal.

In block S300, the identifying module 160 edge-triggers the at least four communication channels 10.

In block S302, the identifying module 160 measures a rise time and a fall time for each of the captured signals in both two transmitting terminals. In the embodiment, the two transmitting terminals may include a sending terminal (ST) and a receiving terminal (RT) of each of the captured signals.

In block S304, the identifying module 160 sets a ST and a RT for the each of the captured signals according to said measurement. In the embodiment, the rise time and fall time of one signal in the ST is larger than that in the RT.

In block S306, the identifying module 160 sets triggering parameters to trigger the oscillograph 1, and acquires the captured signals accord with the triggering parameters. In the embodiment, the triggering parameters may include a triggering mode, a signal transmitting channel, an upper level, a lower level, time and an analyzing type. In one embodiment, the triggering mode is a level trigger, and the time is between the rise/fall time of one signal in the ST and that in the RT.

In block S308, the identifying module 160 determines the ST and RT for each of the acquired signals.

In block S310, the identifying module 160 compares the determined ST of each of the acquired signals with a set ST, and compares the determined RT of each of the acquired signals with a set RT.

If both of the determined ST of one signal is identical with the set ST and the determined RT of the signal is identical with the set RT, in block S310, the identifying module 160 determines that the signal is the test signal. For example, if the determined ST of the signal “A” is identical with the set ST of the signal “A,” and the determined RT of the signal “A” is identical with the set RT of the signal “A,” the identifying module 160 determines the signal “A” is the test signal.

Although certain inventive embodiments of the present disclosure have been specifically described, the present disclosure is not to be construed as being limited thereto. Various changes or modifications may be made to the present disclosure without departing from the scope and spirit of the present disclosure.

What is claimed is:

1. A signal integrity test method for a serial data bus using an oscillograph, the method comprising:
communicating with the serial data bus to obtain signals;
controlling the oscillograph to capture the signals transmitted by each communication channel of the oscillograph;
determining a captured signal to be tested from the captured signals by identifying a time sequence for the captured signals transmitted by each communication channel;
controlling the oscillograph to measure a clock frequency of the test signal by positioning a sequential waveform of the test signal on a central display screen of the oscillograph;
sampling a part of the test signal, positioning the part on the display screen according to the clock frequency and testing the part according to pre-set test items;
constituting a completed signal integrity test of the serial data bus upon a condition that a predetermined number of samples of the test signal is tested; and
generating a test report, and display the test report on the display screen.

2. The method as described in claim 1, wherein the determining block comprises:
edge-triggering the communication channel transmitting each of the captured signals;
measuring a rise time and a fall time of each of the captured signals in both two transmitting terminals;
setting a sending terminal (ST) and a receiving terminal (RT) for the each of the captured signals according to said measurement, wherein the rise time and fall time of one captured signal in the ST is larger than that in the RT;
setting triggering parameters to trigger the oscillograph, and acquiring the captured signals accord with the triggering parameters;
determining the ST and RT for each of the acquired signals;
comparing the determined ST of each of the acquired signals with a set ST and comparing the determined RT of each of the acquired signals with a set RT; and
determining that the signal is the test signal, upon a condition that both of the determined ST of one signal is identical with the set ST and the determined RT of the signal is identical with the set RT.

3. The method as described in claim 2, wherein the triggering parameters comprise a triggering mode, a signal transmitting channel, an upper level, a lower level, time and an analyzing type.

4. The method as described in claim 3, wherein the triggering mode is a level trigger.

5. The method as described in claim 3, wherein the time is between the rise/fall time of one signal in the ST and that in the RT.

6. An oscillograph, comprising:
at least four communication channels being connected to a serial data bus;
a communication unit operable to communicate with the serial data bus to obtain signals;
a control unit operable to control the oscillograph to capture the signals transmitted by each of the at least four communication channels; and
a signal integrity test unit, comprising:
an identifying module operable to determine a captured signal to be tested from the captured signals by identifying a time sequence for the captured signals transmitted by each of the at leas four communication channels;
a signal test module operable to control the oscillograph to measure a clock frequency of the test signal by positioning a sequential waveform of the test signal on a central display screen of the oscillograph, sample a part of the test signal, position the part on the display screen according to the clock frequency, test the part according to pre-set test items, and constituting a completed signal integrity test of the serial data bus upon a condition that a predetermined number of samples of the test signal is tested; and
a generating module operable to generate a test report, and display the test report on the display screen.

7. The oscillograph as described in claim 6, wherein the signal test module determines the test signal from the captured signals by performing the following steps:
edge-triggering the communication channel transmitting each of the captured signals;
measuring a rise time and a fall time of each of the captured signals in both two transmitting terminals;
setting a sending terminal (ST) and a receiving terminal (RT) for the each of the captured signals according to said measurement, wherein the rise time and fall time of one captured signal in the ST is larger than that in the RT;
setting triggering parameters to trigger the oscillograph, and acquiring the captured signals accord with the triggering parameters;
determining the ST and RT for each of the acquired signals;
comparing the determined ST of each of the acquired signals with a set ST and comparing the determined RT of each of the acquired signals with a set RT; and
determining that the signal is the test signal, upon a condition that both of the determined ST of one signal is identical with the set ST and the determined RT of the signal is identical with the set RT.

8. The oscillograph as described in claim 7, wherein the triggering parameters comprise a triggering mode, a signal transmitting channel, an upper level, a lower level, time and an analyzing type.

9. The oscillograph as described in claim 8, wherein the triggering mode is a level trigger.

10. The oscillograph as described in claim 8, wherein the time is between the rise/fall time of one signal in the ST and that in the RT.

11. A storage medium having stored thereon instructions that, when executed by a processor of an oscillograph, causing the oscillograph to complete a signal integrity test method for a serial data bus, wherein the instructions comprises:
communicating with the serial data bus to obtain signals;
controlling the oscillograph to capture the signals transmitted by each communication channel of the oscillograph;
determining a captured signal to be tested from the captured signals by identifying a time sequence for the captured signals transmitted by each communication channel;
controlling the oscillograph to measure a clock frequency of the test signal by positioning a sequential waveform of the test signal on a central display screen of the oscillograph;
sampling a part of the test signal, positioning the part on the display screen according to the clock frequency and testing the part according to pre-set test items;
constituting a completed signal integrity test of the serial data bus upon a condition that a predetermined number of samples of the test signal is tested; and
generating a test report, and display the test report on the display screen.

12. The storage medium as described in claim 11, wherein the determining block comprises:
edge-triggering the communication channel transmitting each of the captured signals;
measuring a rise time and a fall time of each of the captured signals in both two transmitting terminals;
setting a sending terminal (ST) and a receiving terminal (RT) for the each of the captured signals according to said measurement, wherein the rise time and fall time of one captured signal in the ST is larger than that in the RT;
setting triggering parameters to trigger the oscillograph, and acquiring the captured signals accord with the triggering parameters;
determining the ST and RT for each of the acquired signals;
comparing the determined ST of each of the acquired signals with a set ST and comparing the determined RT of each of the acquired signals with a set RT; and
determining that the signal is the test signal, upon a condition that both of the determined ST of one signal is identical with the set ST and the determined RT of the signal is identical with the set RT.

13. The storage medium as described in claim 12, wherein the triggering parameters comprise a triggering mode, a signal transmitting channel, an upper level, a lower level, time and an analyzing type.

14. The storage medium as described in claim 13, wherein the triggering mode is a level trigger.

15. The storage medium as described in claim 13, wherein the time is between the rise/fall time of one signal in the ST and that in the RT.
